(19) United States
(12) Patent Application Publication
(10) Pub. No.: US 2016/0348266 A1
(43) Pub. Date: Dec. 1, 2016

(54) SHADOW MASK CLEANING METHOD AND CLEANING DEVICE THEREOF

(71) Applicant: SHENZHEN CHINA STAR OPTOELECTRONICS TECHNOLOGY CO., Shenzhen, Guangdong (CN)

(72) Inventor: Jinchuan LI, Shenzhen, Guangdong (CN)

(73) Assignee: SHENZHEN CHINA STAR OPTOELECTRONICS TECHNOLOGY CO., Shenzhen, Guangdong (CN)

(21) Appl. No.: 14/407,941

(22) PCT Filed: Nov. 28, 2014
(86) PCT No.: PCT/CN2014/092507

§ 371 Date: Dec. 12, 2014

(30) Foreign Application Priority Data
Nov. 21, 2014 (CN) 201410677403.X

(51) Int. Cl. C25F 1/00

(52) U.S. Cl. CPC C25F 1/00; H01L 51/0011

(57) ABSTRACT

A shadow mask cleaning method and the cleaning device thereof are disclosed. The cleaning method comprises the steps of providing an alkaline conductive solution, and immersing a shadow mask into the alkaline conductive solution; connecting the shadow mask to one electrode selected from an anode or a cathode of a power source, and immersing the other electrode selected from the anode or the cathode of the power source into the alkaline conductive solution; and turning on the power source to generate an ionization reaction in the alkaline conductive solution to form gases, so that pollutants on the shadow mask are taken away from the shadow mask by the gases. By using the above mentioned method, the present invention can remove the pollutants from the shadow masks by the gases and improve the yield of the organic light emitting display panel and reduce the manufacture cost.

### FIELD OF THE INVENTION

The present invention relates to the technological field of the display panel; in particular, to a shadow mask cleaning method and device of the organic light emitting display panel.

### BACKGROUND OF THE INVENTION

The organic light emitting diode is a kind of self light emitting display panel. Because the organic light emitting diode has some advantages such as simple structure, fast response, flexible characteristic, and power saving, the manufacture industry praises it more and more.

Nowadays, the shadow mask is used to deposit the organic light emitting layer of the organic light emitting display panel. With the long time use and depositing amount increasing, the photoresist residuals and the dusts from the surface of the shadow mask and the depositing holes inside gradually accumulate to block the depositing hole, even cause the distortion of the shadow mask, such that the organic material cannot be deposited accurately on the substrate to form an organic light emitting layer and then to affect the yield and increase the manufacturing cost. Otherwise, the manufacture method of the shadow mask also has an photoresist residual issue. If the photoresist residuals on the surface of the shadow mask and inside the depositing hole can be removed efficiently, it results in the low yield and the high cost. However, the detergents and the chemicals for cleaning the shadow mask nowadays only can remove the organic material, and it has very bad cleaning effect for the dust or other particles and it even cannot clean them, so the photoresist residuals and the dusts cannot removed efficiently on the shadow mask, and the yield of the organic light emitting display panel cannot be improved.

### SUMMARY OF THE INVENTION

In light of the conventional problem, the present invention solves the technical problem that is to provide a cleaning method for the shadow mask and a cleaning device thereof to remove the photoresist residuals and the dusts on the shadow mask efficiently, then to improve the yield of the organic light emitting display panel.

In order to solve the above mentioned technical problem, the present invention uses a solution which is to provide a shadow mask cleaning method, comprising: providing an alkaline conductive solution, and immersing the shadow mask into the alkaline conductive solution, wherein the alkaline conductive solution is selected from the group consisting of potassium hydroxide solution or sodium hydroxide solution or combinations thereof and PH of the alkaline conductive solution is larger than or equal to 11; connecting the shadow mask to one electrode selected from an anode or a cathode of a power source, and immersing the other electrode selected from the anode or the cathode of the power source into the alkaline conductive solution; turning on the power source to generate an ionization reaction in the alkaline conductive solution to form gases, and at the same time to vibrate the shadow mask using ultrasound having a predetermined frequency, so that pollutants on the shadow mask are taken away from the shadow mask by the gases

Where, the shadow mask connects to the cathode of the power source and the anode of the power source immerses into the alkaline conductive solution.

Where, a depositing hole is disposed on the shadow mask, and the anode and the cathode of the power source respectively connects to a metal plate, and the step of connecting the shadow mask to one electrode selected from an anode or a cathode of a power source further comprises: arranging a predetermined distance between the shadow mask and the metal plate to make diameter of the gases less than or equal to diameter of the depositing hole when bubbles generates in the alkaline conductive solution move to the shadow mask.

Where, the anode and the cathode of the power source connects to the metal plate having same material with the anode and the cathode, and the manufacturing material of the metal plate comprises cupper.

Where, after turning on the power source to generate an ionization reaction in the alkaline conductive solution at the same time, the cleaning method further comprises: gradually enlarging a discharging current of the power source based on a predetermined interval, and the value of the discharging current is between 100 ampere and 1000 ampere.

In order to solve the above mentioned technical problem, the present invention uses the other technical solution is to provide a shadow mask cleaning method comprises steps of: providing an alkaline conductive solution, and immersing a shadow mask into the alkaline conductive solution; connecting the shadow mask to one electrode selected from an anode or a cathode of a power source, and immersing the other electrode selected from the anode or the cathode of the power source into the alkaline conductive solution; and turning on the power source to generate an ionization reaction in the alkaline conductive solution to form gases, so that pollutants on the shadow mask are taken away from the shadow mask by the gases.

Where, the alkaline conductive solution is selected from the group consisting of potassium hydroxide solution or sodium hydroxide solution or combinations thereof and PH of the alkaline conductive solution is larger than or equal to 11.

Where, the shadow mask connects to the cathode of the power source and the anode of the power source immerses into the alkaline conductive solution.

Where, before the step of immersing the shadow mask into the alkaline conductive solution, the cleaning method further comprises: washing the shadow mask by using an organic solvent to remove an organic material on the shadow mask.

Where, after the step of turning on the power source to generate an ionization reaction in the alkaline conductive solution to form gases, the cleaning method further comprises: vibrating the shadow mask using ultrasonic having a predetermined frequency.

Where, a depositing hole is disposed on the shadow mask, and the anode and the cathode of the power source respectively connects to a metal plate, and the step of connecting the shadow mask to one electrode selected from an anode or a cathode of a power source further comprises: arranging a predetermined distance between the shadow mask and the metal plate to make diameter of the gases less than or equal to diameter of the depositing hole when the bubbles which generate in the alkaline conductive solution move to the shadow mask.

Where, the anode and the cathode of the power source connects to the metal plate having same material with the anode and the cathode, and the manufacturing material of the metal plate comprises cupper.

Where, after the step of turning on the power source to generate an ionization reaction in the alkaline conductive solution at the same time, the cleaning method further comprises: gradually enlarging a discharging current of the power source based on a predetermined interval, and the value of the discharging current is between 100 ampere and 1000 ampere.

In order to solve the above mentioned technical problem, the present invention uses another technical solution is to provide a shadow mask cleaning device comprising a power source and an alkaline conductive solution filled in an electrolytic cell, wherein one electrode of an anode or a cathode of the power source connects to the shadow mask, the other electrode of the anode or the cathode of the power source is immersed into the alkaline conductive solution, and after turning on the power source, the alkaline conductive solution generates an ionization reaction and forms gases to take pollutants away from the shadow mask by using the gases.

Where, the alkaline conductive solution is selected from the group consisting of potassium hydroxide solution or sodium hydroxide solution or combinations thereof and PH of the alkaline conductive solution is larger than or equal to 11 and the shadow mask connects to the cathode of the power source and the anode of the power source immerses into the alkaline conductive solution.

Through the above mentioned solution, the present invention has the advantages: based on the design of the present invention, the shadow mask connects to the anode or the cathode, and the other electrode immerses into the alkaline conductive solution. When turning on the power source, the anode and cathode of the power source discharges to generate the ionization reaction in the alkaline conductive solution and form gases so that pollutants on the shadow mask are taken away from the shadow mask by the gases. Comparing with the conventional cleaning method using the organic solvent, the embodiment of the present invention can remove the photoresist residuals and the dusts on the shadow mask to improve the yield of the organic light emitting display panel and reduce the manufacture cost.

### BRIEF DESCRIPTION OF THE DRAWINGS

FIG. 1 is the flow chart of the shadow mask cleaning method of the first embodiment of the present invention;

FIG. 2 is the lateral view of the shadow mask cleaning device of the preferred embodiment of the present invention;

FIG. 3 is the flow chart of the shadow mask cleaning method of the second embodiment of the present invention.

### DETAILED DESCRIPTION OF THE PREFERRED EMBODIMENTS

Below with reference to the accompanying drawings of the embodiments of the invention, be clear that the technical solution of the embodiment of the present invention, a complete description, it is clear that the described embodiments are merely part of embodiments of the present invention, but not all embodiments. Based on the embodiments of the present invention, and all other embodiments of the skilled in the art without creative efforts made under the obtained fall within the protection scope of the present invention.

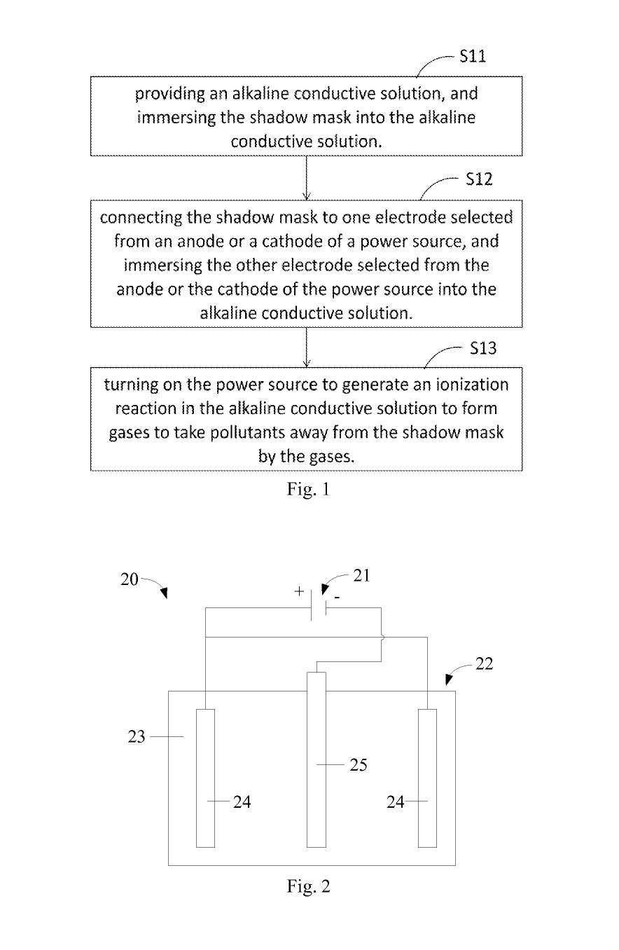

The embodiment of the present invention provides a cleaning method as shown in FIG. 1 based on a cleaning device as shown in FIG. 2. Please refer to FIG. 1 and FIG. 2. The cleaning method of the present embodiment comprises:

Step S11: providing an alkaline conductive solution, and immersing the shadow mask into the alkaline conductive solution.

As shown in FIG. 2, the cleaning device 20 comprises a power source 21 and an alkaline conductive solution 23 filled in an electrolytic cell 22, where PH of the preferred alkaline conductive solution is larger than or equal to 11, and the alkaline conductive solution 23 is selected from the group consisting of potassium hydroxide solution or sodium hydroxide solution or combinations thereof The anode of the power source 21 connects to a metal plate 24, and the cathode of the power source 25 connects to a metal plate 25, i.e. the metal plate 24 and the metal plate 25 are relative to the positive electrode and negative electrode of the power source 21 to constitute an anode and a cathode of an electrolytic cell. The preferred embodiment selects the same material for the metal plate 24 and the metal plate 25 which are both cupper metal.

The embodiment of the present invention is used for manufacturing a shadow mask of an organic emitting layer of an organic light emitting diode, where the shadow mask can be used in manufacturing other device. In view of a plurality of depositing holes disposed on the shadow mask of the organic emitting layer, in the preferable embodiment the area of the plurality of depositing holes of the shadow mask is immersed into the alkaline conductive solution 23 and the whole shadow mask can be immersed into the alkaline conductive solution 23 as well.

Step S12: connecting the shadow mask to one electrode selected from an anode or a cathode of a power source, and immersing the other electrode selected from the anode or the cathode of the power source into the alkaline conductive solution.

Step S13: turning on the power source to generate an ionization reaction in the alkaline conductive solution to form gases to take pollutants away from the shadow mask by the gases.

Please refer to FIG. 2 again. When turning on the power source 21, the anode and the cathode of the power source 21 discharges to generate an ionization reaction in the alkaline conductive solution 23 and form gases. While the gases rise to the liquid level of the alkaline conductive solution 23, the gases take the pollutants away from the surface of the shadow mask and the depositing holes inside. Comparing with the conventional technology of the organic solvent cleaning method, the embodiment can remove the photoresist residuals and the dusts from the surface of the shadow mask and the depositing holes inside so as to enhance the manufacture yield of the organic light emitting diode and reduce the manufacture cost.

It should be noted that, for the composition of the gases generated by the ionization reaction in the alkaline conductive solution 23, and that does not limit the present invention herein. For example, in light of the alkaline conductive solution 23 which is made by mixing potassium hydroxide KOH solution having electronic grade, deionized water and conductive solvent, the water in the alkaline conductive solution 23 is ionized into hydrogen ions H+ and, hydroxide ions OH— and KOH is ionized into potassium K+ and hydroxide ions OH—. Moreover, in the anode, hydroxide ions OH— [symbol] [symbol] take part in the first electrode reaction to produce oxygen O2:

4OH⁻→4e⁻+O₂ [symbol] +2H₂O

In the cathode, hydrogen ions H+ take part in the second electrode reaction to produce hydrogen H2 and potassium K+ take part in the third electrode reaction to produce hydrogen H2.

2H⁺+2e⁻→H₂

[symbol]

2K++2e−+2 H2O→2KOH+H2

[symbol]

Based on the first electrode reaction, the second electrode reaction and the third electrode reaction, the gases generated in the anode area is twice as many as the gases generated in the cathode area, and hence the shadow mask connects to the cathode of the power source 21 preferably in the embodiment of the present invention.

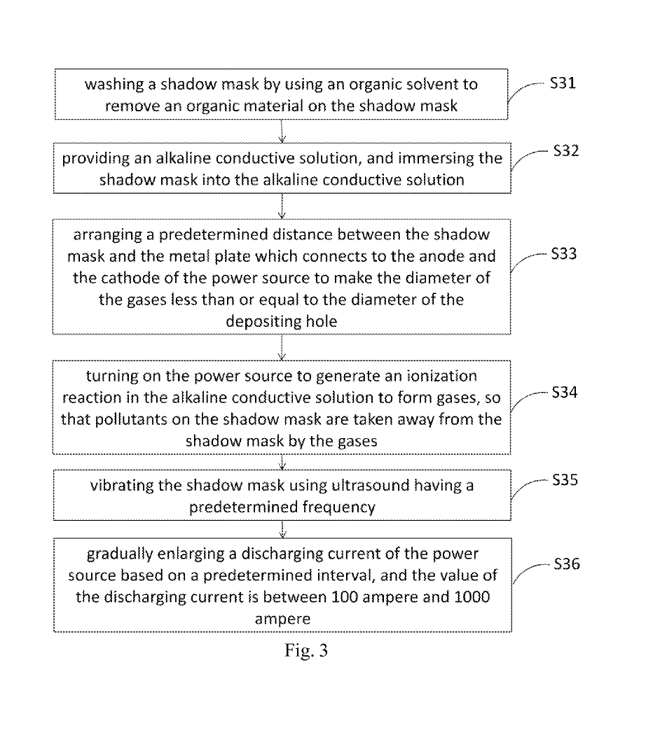

FIG. 3 is a shadow mask cleaning method of the second embodiment of the present invention, which is further described based on the embodiment of the cleaning method shown in FIG. 1. The difference with the first embodiment is that considering not to damage the shadow mask first, the second embodiment discloses how to clean the dust and the photoresist residuals.

Please refer to FIG. 3 combining with FIG. 2. The cleaning method of the embodiment comprises:

Step S31: washing a shadow mask by using an organic solvent to remove an organic material on the shadow mask;

The pollutants comprise organic materials, the photoresist residuals, the dusts and so on. This step uses the conventional organic solvent to remove the organic material, and after washing and cleaning, Step S32 is executed to reduce the pollutant amount by gases.

Step S32: providing an alkaline conductive solution, and immersing the shadow mask into the alkaline conductive solution.

Step S33: arranging a predetermined distance between the shadow mask and the metal plate which connects to the anode and the cathode of the power source to make the diameter of the gases less than or equal to the diameter of the depositing hole.

Specifically, if the shadow mask connects to the anode shown in FIG. 2, the predetermined distance should be arranged between the shadow mask and the metal plate 24; if the shadow mask connects to the cathode shown in FIG. 2, the predetermined distance should be arranged between the shadow mask and the metal plate 25. Because the bubbles which the gases are generated in alkaline conductive solution 23 become larger and larger while it rises to the surface. Moreover, the larger the diameter of the bubbles than the diameters of the depositing holes of the shadow mask the bubbles pass through is, the stronger the force taken the photoresist residuals and the dusts away is, and the better the cleaning effect is.

Step S34: turning on the power source to generate an ionization reaction in the alkaline conductive solution to form gases, so that pollutants on the shadow mask are taken away from the shadow mask by the gases.

Step S35: vibrating the shadow mask using ultrasound having a predetermined frequency.

The step S35 and Step S34 do not have to be in the specific order. Step S34 is executed first and then Step S35 is, or Step S35 is executed first and then Step S34 is.

Otherwise, Steps S34 and S35 are executed at the same time. The embodiment prefers to execute Step S34 at the same time the alkaline conductive solution 23 generates the ionization reaction to form gases after turning on the power source.

While the ionization reaction generates the gases, the shadow mask vibration continues for cleaning the photoresist residuals and the dusts better.

Step S36: gradually enlarging a discharging current of the power source based on a predetermined interval, and the value of the discharging current is between 100 ampere and 1000 ampere.

Because the current enlargement enhances the ionization reaction of the alkaline conductive solution 23, and it generates a large amount of bubbles, the cleaning effect for the photoresist residuals and the dusts by using the impact velocity of the bubbles to prevent the vulnerable shadow mask on distortion resulting from the impact velocity.

It should be noted that, the ranges of the above mentioned discharge current are the inventor's design based on the structural characteristic of the shadow mask and the cleaning effect which the impact velocity of the gases to the photoresist residuals, the dusts and some particles. Therefore, the ranges of the above mentioned discharge current cannot be easily thought by the person who is in the art.

Otherwise, it should be noted that, comparing with the first embodiment as shown in FIG. 1.the additional steps of the second embodiment can be combined with the first embodiment to constitute another embodiment. It is not limited within the embodiment of FIG. 3.

Similarly, the cleaning device provided by the embodiment of the present invention is not limited within the cleaning device 20 in FIG. 2 and only comprises a power source and an alkaline conductive solution filled in the electrolytic cell, where one of the anode and cathode of the power source is selected to connect with the shadow mask and the other one of the anode and cathode of the power source immerses into the alkaline conductive solution. And after turning on the power source, the alkaline conductive solution generates the ionization reaction to form the gases.

In summary, the present invention generates the ionization reaction in the alkaline conductive solution and forms the gases through the discharge by the anode and the cathode of the power source. The pollutants on the surface of the shadow mask and inside the depositing holes are taken away by the gases. Comparing with the traditional art of the cleaning method using organic solvent, the embodiment of the present invention removes the photoresist residuals and the dusts from the surface of the shadow mask efficiently to improve the yield of the organic light emitting diode and cost down the manufacturing cost.

The above are only embodiments of the present invention, the patent does not therefore limit the scope of the invention, any use of the accompanying drawings and the description of the present invention is made equivalent structures or equivalent conversion process, either directly or indirectly in the other the relevant art, are included within the same reason the patent scope of the present invention.

What is claimed is:

1. A shadow mask cleaning method, which characterized in that the cleaning method comprises:
washing a shadow mask by using an organic solvent to remove an organic material on the shadow mask;
providing an alkaline conductive solution, and immersing the shadow mask into the alkaline conductive solution, wherein the alkaline conductive solution is selected from the group consisting of potassium hydroxide solution or sodium hydroxide solution or combinations thereof and PH of the alkaline conductive solution is larger than or equal to 11;
connecting the shadow mask to one electrode selected from an anode or a cathode of a power source, and immersing the other electrode selected from the anode or the cathode of the power source into the alkaline conductive solution; and
turning on the power source to generate an ionization reaction in the alkaline conductive solution to form gases, and at the same time to vibrate the shadow mask using ultrasound having a predetermined frequency, so that pollutants on the shadow mask are taken away from the shadow mask by the gases.

2. The cleaning method as claimed in claim 1, which characterized in that the shadow mask connects to the cathode of the power source and the anode of the power source immerses into the alkaline conductive solution.

3. The cleaning method as claimed in claim 1, which characterized in that a depositing hole is disposed on the shadow mask, and the anode and the cathode of the power source respectively connects to a metal plate, and the step of connecting the shadow mask to one electrode selected from an anode or a cathode of a power source further comprises:
arranging a predetermined distance between the shadow mask and the metal plate to make diameter of the gases less than or equal to diameter of the depositing hole when bubbles which generate in the alkaline conductive solution move to the shadow mask.

4. The cleaning method as claimed in claim 1, which characterized in that the anode and the cathode of the power source connects to the metal plate having same material with the anode and the cathode, and the manufacturing material of the metal plate comprises cupper.

5. The cleaning method as claimed in claim 1, which characterized in that after the step of turning on the power source to generate the ionization reaction in the alkaline conductive solution at the same time, the cleaning method further comprises:
gradually enlarging a discharging current of the power source based on a predetermined interval, and the value of the discharging current is between 100 ampere and 1000 ampere.

6. A shadow mask cleaning method, which characterized in that the cleaning method comprises:
providing an alkaline conductive solution, and immersing a shadow mask into the alkaline conductive solution;
connecting the shadow mask to one electrode selected from an anode or a cathode of a power source, and immersing the other electrode selected from the anode or the cathode of the power source into the alkaline conductive solution; and
turning on the power source to generate an ionization reaction in the alkaline conductive solution to form gases, so that pollutants on the shadow mask are taken away from the shadow mask by the gases.

7. The cleaning method as claimed in claim 6, which characterized in that the alkaline conductive solution is selected from the group consisting of potassium hydroxide solution or sodium hydroxide solution or combinations thereof and PH of the alkaline conductive solution is larger than or equal to 11.

8. The cleaning method as claimed in claim 7, which characterized in that the shadow mask connects to the cathode of the power source and the anode of the power source immerses into the alkaline conductive solution.

9. The cleaning method as claimed in claim 6, which characterized in that before the step of immersing the shadow mask into the alkaline conductive solution, the cleaning method further comprises:
washing the shadow mask by using an organic solvent to remove an organic material on the shadow mask.

10. The cleaning method as claimed in claim 6, which characterized in that after the step of turning on the power source to generate an ionization reaction in the alkaline conductive solution to form gases, the cleaning method further comprises:
vibrating the shadow mask using ultrasonic having a predetermined frequency.

11. The cleaning method as claimed in claim 6, which characterized in that a depositing hole is disposed on the shadow mask, and the anode and the cathode of the power source respectively connects to a metal plate, and the step of connecting the shadow mask to one electrode selected from an anode or a cathode of a power source further comprises:
arranging a predetermined distance between the shadow mask and the metal plate to make diameter of the gases less than or equal to diameter of the depositing hole when bubbles generates in the alkaline conductive solution move to the shadow mask.

12. The cleaning method as claimed in claim 11, which characterized in that the anode and the cathode of the power source connects to the metal plate having same material with the anode and the cathode, and the manufacturing material of the metal plate comprises cupper.

13. The cleaning method as claimed in claim 11, which characterized in that after the step of turning on the power source to generate an ionization reaction in the alkaline conductive solution at the same time, the cleaning method further comprises:
gradually enlarging a discharging current of the power source based on a predetermined interval, and the value of the discharging current is between 100 ampere and 1000 ampere.

14. A shadow mask cleaning device, which characterized in that the cleaning device comprises a power source and an alkaline conductive solution filled in an electrolytic cell, wherein one electrode of an anode or a cathode of the power source connects to the shadow mask, the other electrode of the anode or the cathode of the power source is immersed into the alkaline conductive solution, and after turning on the power source, the alkaline conductive solution generate an ionization reaction and form gases to take pollutants away from the shadow mask by using the gases.

15. The cleaning device as claimed in claim 9, which characterized in that the alkaline conductive solution is selected from the group consisting of potassium hydroxide solution or sodium hydroxide solution or combinations thereof and PH of the alkaline conductive solution is larger than or equal to 11 and he shadow mask connects to the cathode of the power source and the anode of the power source immerses into the alkaline conductive solution.
